(19) United States
(12) Patent Application Publication
(10) Pub. No.: US 2024/0319593 A1
(43) Pub. Date: Sep. 26, 2024

(54) THINNER COMPOSITION AND METHOD OF TREATING SURFACE OF SEMICONDUCTOR SUBSTRATE BY USING THE SAME

(71) Applicant: Samsung Electronics Co., Ltd., Suwon-si (KR)

(72) Inventors: Yool Kang, Suwon-si (KR); Taehui Kwon, Suwon-si (KR); Dongjun Kim, Suwon-si (KR); Ahram Suh, Suwon-si (KR); Miyeon Jung, Suwon-si (KR); Samjong Choi, Suwon-si (KR); Ohhwan Kweon, Hwaseong-si (KR); Minki Kim, Hwaseong-si (KR); Jaehyun Kim, Hwaseong-si (KR); Sunggun Shin, Hwaseong-si (KR); Seungryul Yoo, Hwaseong-si (KR); Heekyung Lee, Hwaseong-si (KR)

(73) Assignees: Samsung Electronics Co., Ltd., Suwon-si (KR); Dongjin Semichem Co., Ltd., Hwaseong-si (KR)

(21) Appl. No.: 18/381,335

(22) Filed: Oct. 18, 2023

(30) Foreign Application Priority Data
Mar. 24, 2023 (KR) 10-2023-0039213

(51) Int. Cl. G03F 7/004; G03F 7/20

(52) U.S. Cl. CPC G03F 7/0048; G03F 7/2004

(57) ABSTRACT

Provided are a thinner composition, which may be generally used for an extreme ultraviolet (EUV) photoresist as well as KrF and ArF photoresists and exhibits improved performance in reduced resist coating (RRC) and edge bead removal (EBR), and which has an excellent pipe cleaning capability, and a method of treating a substrate surface by using the thinner composition. The thinner composition includes a C2-C4 alkylene glycol C1-C4 alkyl ether acetate, a C2-C3 alkylene glycol C1-C4 alkyl ether, and a cycloketone.

### CROSS-REFERENCE TO RELATED APPLICATION

This application is based on and claims priority under 35 U.S.C. § 119 to Korean Patent Application No. 10-2023-0039213, filed on Mar. 24, 2023, in the Korean Intellectual Property Office, the disclosure of which is incorporated by reference herein in its entirety.

### BACKGROUND

The inventive concept relates to a thinner composition and a method of treating a surface of a semiconductor substrate by using the thinner composition, and more particularly, to a thinner composition, with which a reduced resist coating (RRC) process may be effectively performed, which has an improved edge bead removal (EBR) effect, and which has an excellent pipe cleaning capability, and to a method of treating a surface of a semiconductor substrate by using the thinner composition.

Fine circuit patterns, such as semiconductor integrated circuits, are fabricated by uniformly coating photoresists, which include photoresist compounds and solvents, on conductive metal films, oxide films, or the like, which are formed on substrates, by spin coating methods, followed by sequentially performing exposure, development, etching, and strip processes.

In spin coating methods, RRC processes have been proposed, in which the amounts of photoresists used are reduced by coating thinner compositions first on wafer surfaces before photoresists are coated.

In addition, because, after photoresists are coated, exposure processes corresponding to subsequent processes thereto are performed by exposing coated photoresist films to short-wavelength light in the ultraviolet range to form intended fine patterns, the exposure processes are significantly sensitive to internal and external contamination. When unnecessary photoresist residues after coating and other contaminants remain on edge portions or backside portions of substrates, such photoresist residues and other contaminants may be serious contamination sources in subsequent exposure processes. Therefore, EBR processes or back rinse processes have been proposed for removing unnecessary photoresist residues and contaminants, which are on edge portions or backside portions of substrates, before exposure processes are performed.

Such RRC processes, EBR processes, or back rinse processes are performed by using thinner compositions for photoresist removal.

According to the related art, krypton fluoride (KrF) thinners and argon fluoride (ArF) thinners have been mainly used as thinner compositions for photoresist removal. However, to improve the degrees of integration of semiconductor devices, as the use of extreme ultraviolet (EUV) photoresists, which are more facilitated to form fine pattern, comes to the fore, it is required to develop thinner compositions suitable for EUV photoresists. For example, when KrF and ArF thinner compositions according to the related art are used to coat EUV photoresists in RRC processes, there is a drawback of low coating uniformity. In addition, when KrF and ArF thinner compositions according to the related art are used to remove EUV photoresists, there is a drawback in that residual photoresists may cause particle defects or poor EBR profile. Such drawbacks eventually result in an issue in that next-generation semiconductor processes requiring fine pattern formation are not allowed to be satisfactorily implemented.

Therefore, to stably perform RRC processes and EBR processes, there is a demand to develop a thinner composition, which may be generally and widely used for EUV photoresists as well as KrF and ArF photoresists.

### SUMMARY

The inventive concept provides a thinner composition, which may be generally and widely used for EUV photoresists (including EUV multi-patterning photoresists and high numerical aperture EUV photoresists) as well as KrF and ArF photoresists, and which exhibits improved performance in reduced resist coating (RRC) and edge bead removal (EBR), as compared with existing thinners.

The inventive concept also provides a thinner composition having an excellent pipe cleaning capability.

The inventive concept also provides a method of treating a substrate surface by using the thinner composition.

In addition, the inventive concept is not limited to the aspects set forth above, and the above and other aspects of the inventive concept can be clearly understood by those of ordinary skill in the art from the following detailed description.

According to an aspect of the inventive concept, there is provided a thinner composition including a C2-C4 alkylene glycol C1-C4 alkyl ether acetate, a C2-C3 alkylene glycol C1-C4 alkyl ether, and a cycloketone.

According to another aspect of the inventive concept, there is provided a thinner composition including about 20 wt % to about 40 wt % of a C2-C3 alkylene glycol C1-C4 alkyl ether and about 25 wt % to about 45 wt % of a cycloketone, based on the total weight of the thinner composition, wherein a material constituting the balance in the thinner composition includes a C2-C4 alkylene glycol C1-C4 alkyl ether acetate.

According to another aspect of the inventive concept, there is provided a method of treating a substrate surface, the method including coating a thinner composition on a substrate, forming a photoresist film by applying a photoresist composition to the substrate and heating the substrate, exposing at least a portion of the photoresist film to light, and developing the photoresist film that is exposed to light, wherein the thinner composition includes a C2-C4 alkylene glycol C1-C4 alkyl ether acetate, a C2-C3 alkylene glycol C1-C4 alkyl ether, and a cycloketone.

### BRIEF DESCRIPTION OF THE DRAWINGS

Embodiments will be more clearly understood from the following detailed description taken in conjunction with the accompanying drawings in which:

FIG. 1 illustrates results showing contact angles when an extreme ultraviolet (EUV) photoresist is coated and images of substrate edge humps after an edge bead removal (EBR) process is performed, after a thinner composition of Example 6 according to the inventive concept and a thinner composition of Comparative Example 7 are each coated on a substrate surface;

FIG. 2 illustrates results showing images of EBR profiles of an EUV photoresist, after a reduced resist coating (RRC) process is performed by using thinner compositions of Examples 1 to 6 according to the inventive concept and Comparative Examples 1 to 6;

FIG. 3 is a graph illustrating results of the coating uniformity of an ArF photoresist, after an RRC process is performed by using thinner compositions of Example 6 according to the inventive concept and Comparative Example 7;

FIGS. 4A to 4C each illustrate results of evaluating a dissolving capability of a thinner composition for cleaning with respect to a KrF photoresist, an ArF photoresist, and an EUV photoresist; and

FIG. 5 illustrates results of evaluating the degrees of tearing of an EUV photoresist, when an RRC process is performed by using thinner compositions of Examples 1 to 6 according to the inventive concept and Comparative Examples 1 to 6.

### DETAILED DESCRIPTION OF THE EMBODIMENTS

Because embodiments of the inventive concept may be variously modified and changed and may be implemented in various different ways, particular embodiments will be illustrated in the accompanying drawings and described in detail in the following detailed description. However, it is not intended to limit the scope of the inventive concept to the particular embodiments, and all changes, modifications, equivalents, and replacements made without departing from the spirit and scope of the inventive concept should be construed as falling within the scope of the inventive concept. In describing embodiments, when it is determined that specific descriptions of relevant techniques known in the art may make the subject matter of the inventive concept ambiguous, detailed descriptions thereof are omitted.

Whenever a range of values is described, the range includes all values falling within the range as explicitly written and also includes the boundaries of the range. Therefore, the range of “X to Y” includes all values between X and Y and also includes X and Y together therewith.

A photoresist composition according to some embodiments may include an organic solvent, a matrix material, and the like.

A thinner composition according to the inventive concept may include a C2-C4 alkylene glycol C1-C4 alkyl ether acetate. The C2-C4 alkylene glycol C1-C4 alkyl ether acetate has an excellent dissolving capability with respect to other types of photoresists and functions to impart a uniform coating to a photoresist. The C2-C4 alkylene portion of the compound can be ethylene, propylene or butylene, whereas the C1-C4 alkyl portion of the compound can be for example a monoalkyl, such as monomethyl, monoethyl, monopropyl or monobutyl. For example, the C2-C4 alkylene glycol C1-C4 alkyl ether acetate may include at least one selected from the group consisting of propylene glycol monomethyl ether acetate (PGMEA), propylene glycol monoethyl ether acetate (PGEEA), propylene glycol monobutyl ether acetate (PGBEA), ethylene glycol monomethyl ether acetate (EGMEA), ethylene glycol monoethyl ether acetate (EGEEA), and ethylene glycol monobutyl acetate (EGBEA). The C2-C4 alkylene glycol C1-C4 alkyl ether acetate may be present in an amount of about 30 wt % to about 80 wt %, about 35 wt % to about 65 wt %, about 50 wt % to about 80 wt %, or about 20 wt % to about 40 wt %, based on the total weight of the thinner composition.

The thinner composition according to the inventive concept may further include a C2-C3 alkylene glycol C1-C4 alkyl ether. The C2-C3 alkylene glycol C1-C4 alkyl ether may be present in an amount of about 10 wt % to about 50 wt %, about 20 wt % to about 40 wt %, or about 25 wt % to about 35 wt %, based on the total weight of the thinner composition. The C2-C3 alkylene portion can be ethylene or propylene, and the C1-C4 alkyl portion can be a C1-C4 isoalkyl such as isopropyl or isobutyl, or a monoalkyl such as monomethyl, monoethyl, monopropyl or monobutyl. The C2-C3 alkylene glycol C1-C4 alkyl ether may include at least one selected from the group consisting of ethylene glycol isopropyl ether, ethylene glycol monopropyl ether (propyl cellosolve), ethylene glycol monobutyl ether, ethylene glycol monoethyl ether, and propylene glycol monomethyl ether (PGME).

The thinner composition according to the inventive concept may further include a cycloketone. The cycloketone may include, for example, cyclopentanone. As another example, the cycloketone may include at least one of cyclohexanone and cycloheptanone. The cycloketone may be present in an amount of about 2 wt % to about 40 wt %, about 5 wt % to about 30 wt %, about 5 wt % to about 20 wt %, about 20 wt % to about 30 wt %, or about 25 wt % to about 45 wt %, based on the total weight of the thinner composition. Cyclopentanone may increase the polarity of the thinner composition and thus improve a dissolving capability of the thinner composition with respect to KrF, ArF, and EUV photoresists having high polarity. In particular, cyclopentanone has high volatility and excellent solubility, and thus, the thinner composition according to the inventive concept may provide better effects in edge bead removal (EBR) or reduced resist coating (RRC) than thinner compositions according to the related art. When the respective ranges of amounts of the components set forth above are satisfied, the thinner composition may have excellent dissolving capabilities and compatibility with respect to any photoresists and may provide excellent RRC and EBR characteristics by implementing appropriate surface tension.

As a specific example, the thinner composition according to the inventive concept may include PGMEA, ethylene glycol monopropyl ether, and cyclopentanone.

The thinner composition according to the inventive concept may further include a surfactant. The surfactant may include, but is not limited to, a silicone-based surfactant, a fluorine-based surfactant, a nonionic surfactant, or an ionic surfactant. The surfactant may be present in an amount of about 0.1 wt % in the thinner composition according to the inventive concept.

In addition, to provide even better effects, the thinner composition according to the inventive concept may include general additives in addition to the components set forth above.

The thinner composition according to the inventive concept may be used in an RRC process and thus facilitate the reduction of usage amounts of a photoresist and a bottom anti-reflective coating (BARC) and the uniform coating thereof. The RRC process may be performed to improve the spreadability and uniformity of a photoresist. In addition, the thinner composition according to the inventive concept may provide excellent performance even when a BARC or an unnecessary portion of a photoresist is removed after the photoresist is coated, and may allow a rework process, a wafer backside cleaning process, or the like to be efficiently performed.

The thinner composition according to the inventive concept may be applied to a photosensitive resin, which uses high energy rays with a wavelength of 500 nm or less, ultraviolet rays, X-rays, and the like as a light source, and here, the photosensitive resin may include, for example, a KrF photoresist or an ArF photoresist. The thinner composition according to the inventive concept may be used in a process that uses an extreme ultraviolet (EUV) photoresist.

The thinner composition according to the inventive concept may be used in a fabrication process of a semiconductor device or a thin-film transistor liquid crystal display device to remove an unnecessary photosensitive film by spraying the thinner composition to an edge portion and a backside portion of a substrate, on which a photosensitive resin composition is coated. Subsequently, general processes known in the art regarding the fabrication of a semiconductor device and a thin-film transistor liquid crystal display device may be performed.

The thinner composition according to the inventive concept may remove, uniformly and in a short time, an unnecessary photoresist generated on an edge portion or a backside portion of a substrate due to the curing of the substrate that is used for the fabrication of a semiconductor device. In addition, the thinner composition according to the inventive concept may have an excellent dissolving capability with respect to various photoresists and BARCs and may exhibit improved performance in RRC, EBR, rework, and photoresist coating. In addition, the thinner composition according to the inventive concept has an excellent capability of dissolving photoresists and anti-reflective coatings, which have high polar structures, and thus, does not generate a phenomenon of clogging a drain port after the end of respective processes of RRC, EBR, and wafer backside cleaning and after the end of a process of wafer frontside pretreatment prior to photoresist coating, thereby helping the improvement of productivity.

In particular, the thinner composition according to the inventive concept may be more effectively used for RRC, EBR, rework, wafer backside cleaning, and pipe cleaning processes, which are based on EUV photoresists.

Hereinafter, the inventive concept is described in more detail with reference to Examples and Comparative Examples. However, these Examples and Comparative Examples are provided for illustration only and the inventive concept is not limited thereto and may be variously changed and modified.

Examples 1 to 8 and Comparative Examples 1 to 11: Preparation of thinner composition

In semiconductor fabrication processes, various contamination sources, such as organic materials, metal ions, and particles, are causes of pattern defects and thus are factors for generating defects and deteriorating yield. Therefore, when a thinner composition was prepared, the concentration of metal ions was limited to a minimum, and respective raw materials were maintained in a high purity state through various processes. The processes of maintaining the respective raw materials in a high purity state are as follows.

The respective raw materials, which were purified to a purity of 99.9% or more to have a total metal content of 1 ppb or less, passes through a pre-filter made of a nano-grade membrane material and were introduced into a batch-type manufacturing tank according to each composition listed in Table 1, followed by performing a mixing and filter circulation process for a certain period of time. In a manner in which the manufacturing tank was purged with nitrogen and filtration was performed by a nano-grade membrane filter to fill the manufacturing tank with a product, thinner compositions of Examples 1 to 8 and Comparative Examples 1 to 11 were prepared.

TABLE 1

| Component (wt %) | | | | | | | | | | |
|---|---|---|---|---|---|---|---|---|---|---|
| PGMEA | PC | CPN | nBA | EEP | PGME | HBM | EL | PGMEP | HC | Sur |

| | | | | | | | | | | | |
|---|---|---|---|---|---|---|---|---|---|---|---|
| Example | 1 | 80 | 15 | 5 | | | | | | | |
| | 2 | 70 | 20 | 10 | | | | | | | |
| | 3 | 65 | 30 | 5 | | | | | | | |
| | 4 | 60 | 20 | 20 | | | | | | | |
| | 5 | 50 | 30 | 20 | | | | | | | |
| | 6 | 65 | 30 | 5 | | | | | | | 0.1 |
| | 7 | 65 | | 5 | | | 30 | | | | |
| | 8 | 35 | | 35 | | | 30 | | | | |
| Comparative | 1 | 30 | | | | | 70 | | | | |
| Example | 2 | 70 | | | 30 | | | | | | |
| | 3 | 70 | | | | 30 | | | | | |
| | 4 | 60 | | | 10 | | 30 | | | | |
| | 5 | 60 | | | | 10 | 30 | | | | |
| | 6 | 70 | | | 30 | | | | | | 0.1 |
| | 7 | 50 | | | | | | 40 | 10 | | |
| | 8 | | 30 | 5 | 60 | | | | | | |
| | 9 | 65 | | 5 | | 30 | | | | | |
| | 10 | 65 | 30 | | | | | | 5 | | |
| | 11 | 65 | | 5 | | | | | | 30 | |

The numerical values written in Table 1 are in units of wt %. In Table 1, PGMEA refers to propylene glycol monomethyl ether acetate. PC refers to Propyl Cellosolve (ethylene glycol monopropyl ether). CPN refers to cyclopentanone. nBA refers to n-butyl acetate. EEP refers to ethyl 3-ethoxypropionate. PGME refers to propylene glycol monomethyl ether. HBM refers to methyl 2-hydroxyisobutyrate. EL refers to ethyl lactate. HC refers to Hexyl Cellosolve (ethylene glycol mono hexyl ether). Sur refers to a silicone-based surfactant.

The following Table 2 shows a polarity range for each solvent of Table 1.

TABLE 2

| Solvent | PGMEA | PC | CPN | nBA | EEP | PGME | HBM | EL | HC |
|---|---|---|---|---|---|---|---|---|---|
| Polarity | 5.6 | 8.7 | 11.9 | 3.7 | 3.3 | 6.3 | 6.1 | 7.6 | 5.5 |
| range | | | | | | | | | |
| (dP) | | | | | | | | | |

### Experimental Example 1: Evaluation of RRC and EBR Performance Regarding EUV Photoresist

A test was performed in such a manner that a thinner composition was coated on a 12-inch oxidized silicon substrate by an RRC coating process, followed by depositing an EUV photoresist on the 12-inch oxidized silicon substrate, followed by determining a contact angle. Here, the contact angle indicates wetting between two materials, such that the compatibility between the two materials is higher as the contact angle is smaller.

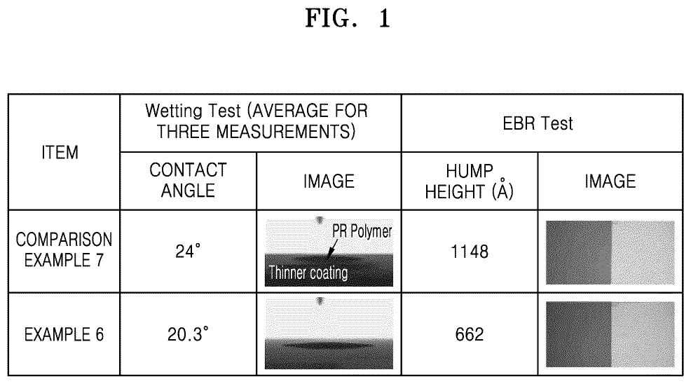

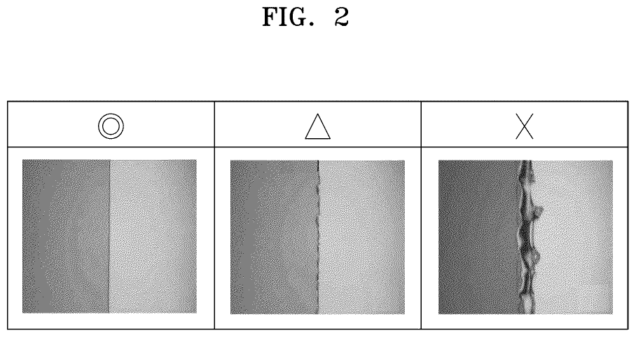

Referring to FIG. 1, when RRC performance evaluation was performed on the thinner compositions of Example 6 and Comparative Example 7, it can be confirmed that the contact angle (20.3°) in the case of using the thinner composition of Example 6 was less than the contact angle (24°) in the case of using the thinner composition of Comparative Example 7. This means that the thinner composition of Example 6 has better wettability with respect to an EUV photoresist than the thinner composition of Comparative Example 7, and that the use of the thinner composition of Example 6 may improve the RRC performance due to the high compatibility thereof with an EUV photoresist.

Next, an EUV photoresist was coated on the 12-inch oxidized silicon substrate, followed by performing an EBR test in which an unnecessary portion of the EUV photoresist in an edge region of the substrate was removed by using each of the thinner compositions of Example 6 and Comparative Example 7.

Referring to FIG. 1, when EBR profiles obtained using the thinner compositions of Example 6 and Comparative Example 7 were compared, although the thinner compositions of Example 6 and Comparative Example 7 appeared to have similar photoresist removal capabilities because photoresist tailing in the edge region of the substrate was not observed by the naked eye for both of the thinner compositions of Example 6 and Comparative Example 7, it was confirmed that, when the height of a photoresist hump at an edge of the substrate was measured, the hump height according to the thinner composition of Example 6 was 662 Å and the hump height according to the thinner composition of Comparative Example 7 was 1148 Å. From these results, it can be confirmed that the thinner composition of Example 6 has better dissolving capability and compatibility with respective to an EUV photoresist than the thinner composition of Comparative Example 7.

### Experimental Example 2: Evaluation of Substrate Defects Before and After RRC Coating Regarding EUV Photoresist

A test was performed to compare substrate defects before and after an EUV photoresist is coated at a flow rate of 1 cc on a 12-inch oxidized silicon substrate by an RRC method (checked by SP5 defect measurement equipment having a size detection capability of 26 nm or more). In the above test, there was no significant difference in test results between the thinner composition of Example 6 and the thinner composition of Comparative Example 7, and it was confirmed that both of the thinner compositions are at a level of being applicable to production. Good results of the above test may refer to excellent dissolving capabilities with respect to an EUV photoresist.

### Experimental Example 3: Evaluation of Reduction in Usage Amount of EUV Photoresist

An RRC process was performed on a 12-inch oxidized silicon substrate by using each of the thinner compositions of Example 6 and Comparative Example 7, and then, it was checked whether an EUV photoresist is coated on the entire surface of the substrate when the coating of the EUV photoresist was performed in different amounts of 0.5 cc, 0.6 cc, 0.7 cc, 0.8 cc, and 0.9 cc. Results of the test are shown in Table 3.

TABLE 3

| | 0.5 cc | 0.6 cc | 0.7 cc | 0.8 cc | 0.9 cc |
|---|---|---|---|---|---|
| Comparative | X | Δ | ◯ | ◯ | ◯ |
| Example 7 | | | | | |
| Example 6 | Δ | ◯ | ◯ | ◯ | — |

In Table 3, when observation was performed by the naked eye, “O” means that the degree of coating of the photoresist was extremely good because 99% or more of the substrate area was coated with the photoresist, “Δ” means that 80% or more of the substrate area was coated with the photoresist, and “X” means that the coating of the photoresist was incomplete because an outer portion of the substrate was not coated with the photoresist and suffered from tearing.

Referring to Table 3, it was confirmed that, in the case of using the thinner composition of Comparative Example 7, while the degree of coating of the photoresist was good only using up to 0.7 cc of the photoresist, in the case of using the thinner composition of Example 6, the degree of coating of the photoresist was good even when the RRC process was performed using 0.6 cc of the photoresist. Comparing with the case where 1.4 cc of the EUV photoresist is required when the coating of the EUV photoresist is performed without the RRC process, it can be confirmed that the photoresist reduction effects in respectively performing the RRC processes using the thinner compositions of Comparative Example 7 and Examples 6 are 50% and 57%, respectively.

From the evaluation results, it can be numerically confirmed that the thinner composition of Example 6 may improve the RRC performance due to the high compatibility between the thinner composition of Example 6 and the EUV photoresist.

### Experimental Example 4: Evaluation of Coating Uniformity of EUV Photoresist

An RRC process was performed on a 12-inch oxidized silicon substrate by using each of the thinner compositions of Example 6 and Comparative Example 7, and then, coating uniformity was measured on three EUV photoresists. The three EUV photoresists are represented hereinafter by EUV PR2, EUP PR3, and EUV PR4, respectively. Each of EUV PR2, EUP PR3, and EUV PR4 was coated in an amount of 0.5 cc, and the coating uniformity was evaluated by measuring the thicknesses of each photoresist film in a linear 29-point mode by using film thickness measurement equipment. The maximum and minimum values of the thicknesses of the coated photoresist film and a difference between the maximum and minimum values are shown as numerical values in Table 4. All the values written in Table 4 are in units of Å. As can be seen in Table 4 Example 6 (with PR 3) was able to achieve a difference between the maximum and minimum values of the thickness of the coated photoresist film of less than 6 Å.

TABLE 4

| | Uniformity | | | | | | | | |
|---|---|---|---|---|---|---|---|---|---|
| | EUV PR 2 | | | EUV PR 3 | | | EUV PR 4 | | |
| | Min | Max | Diff | Min | Max | Diff | Min | Max | Diff |
| Comparative | 354.06 | 374.52 | 20.46 | 343.70 | 351.16 | 7.46 | 594.93 | 612.32 | 17.40 |
| Example 7 | | | | | | | | | |
| Example 6 | 358.31 | 373.89 | 15.58 | 345.43 | 350.88 | 5.45 | 600.12 | 612.60 | 12.48 |

Referring to Table 4, it can be seen that, in the case of performing the RRC process by using the thinner composition of Example 6, all of EUV PR2, EUP PR3, and EUV PR4 have smaller differences between the maximum and minimum values of the photoresist film thickness than in the case of performing the RRC process by using the thinner composition of Comparative Example 7. That is, it can be confirmed that, in the case of using the thinner composition of Example 6, even when the coating is performed with a small amount of an EUV photoresist, the photoresist is uniformly coated on the entire area of a substrate to allow a thickness variation to be small. From the evaluation results, it can be numerically confirmed that the performance of the RRC process using the thinner composition of Example 6 are improved.

### Experimental Example 5: Evaluation of Dissolving Capability of Thinner Composition with Respect to EUV Photoresist

An EUV photoresist was coated on a 12-inch oxidized silicon substrate, and then, a rework test was performed in such a manner that the photoresist on the substrate is removed by using each of the thinner compositions of Examples 1 to 8 and Comparative Examples 1 to 11. In the rework test, 20 cc of each thinner composition was applied on the photoresist-coated substrate and rotated, and then, it was evaluated whether the photoresist is completely removed. Results of the test are shown in Table 5. Three EUV photoresists used in the test are represented hereinafter by EUV PR 1, EUV PR 5, and EUV PR 6, respectively.

TABLE 5

| Comparison | | | | | | | | | | | | | | | | | | | |
|---|---|---|---|---|---|---|---|---|---|---|---|---|---|---|---|---|---|---|---|
| of Rework | Example | | | | | | | | Comparative Example | | | | | | | | | | |
| performance | 1 | 2 | 3 | 4 | 5 | 6 | 7 | 8 | 1 | 2 | 3 | 4 | 5 | 6 | 7 | 8 | 9 | 10 | 11 |
| EUV PR 1 | ◯ | ◯ | ◯ | ◯ | ◯ | ◯ | ◯ | ◯ | Δ | Δ | X | Δ | X | X | X | X | X | X | X |
| EUV PR 5 | ◯ | ◯ | ◯ | ◯ | ◯ | ◯ | ◯ | ◯ | Δ | Δ | X | Δ | Δ | X | X | X | X | X | X |
| EUV PR 6 | Δ | ◯ | Δ | ◯ | ◯ | ◯ | ◯ | ◯ | Δ | X | X | X | Δ | X | X | X | X | X | X |

In Table 5, “O” means that 90% or more of the photoresist was removed after the rework test, “Δ” means that 50% or less of the photoresist was removed after the rework test, and “X” means that 20% or less of the photoresist was removed after the rework test.

Referring to Table 5, it can be seen that the thinner composition of Example 6 has a good dissolving capability with respect to all of EUV PR 1, EUV PR 5, and EUV PR 6. Also, all of Examples 1 to 8 had good dissolving capability particularly for EUV PR 1 and EUV PR 5 as compared to Comparative Examples 1 to 11.

### Experimental Example 6: Evaluation of EBR Performance of Thinner Composition with Respect to EUV Photoresist

An EUV photoresist was coated on a 12-inch oxidized silicon substrate, and then, an EBR test was performed in such a manner that an unnecessary portion of the photoresist in an edge region of the substrate is removed by using each of the thinner compositions of Examples 1 to 8 and Comparative Examples 1 to 11. Results of the test are shown in the following Table 6.

TABLE 6

| Comparison | | | | | | | | | | | | | | | | | | | |
|---|---|---|---|---|---|---|---|---|---|---|---|---|---|---|---|---|---|---|---|
| of EBR | Example | | | | | | | | Comparative Example | | | | | | | | | | |
| performance | 1 | 2 | 3 | 4 | 5 | 6 | 7 | 8 | 1 | 2 | 3 | 4 | 5 | 6 | 7 | 8 | 9 | 10 | 11 |
| EUV PR 1 | ◯ | ◯ | ◯ | ◯ | ◯ | ◯ | ◯ | ◯ | Δ | Δ | X | Δ | Δ | X | X | X | X | X | X |
| EUV PR 5 | ◯ | ◯ | ◯ | ◯ | ◯ | ◯ | ◯ | ◯ | X | Δ | Δ | Δ | X | Δ | Δ | Δ | Δ | Δ | X |
| EUV PR 6 | ◯ | ◯ | ◯ | Δ | Δ | ◯ | ◯ | ◯ | Δ | Δ | X | Δ | Δ | X | X | X | X | Δ | X |

In Table 6, when EBR uniformity in the edge region of the substrate was measured after the EBR, “O” means that 80% or more of the edge region showed a removal state of a good straight shape, “Δ” means that 50% or more of the edge region showed a removal state of a good straight shape, and “X” means that a photoresist tailing phenomenon occurred in the edge region.

Referring to Table 6, it can be confirmed that the thinner composition of Example 6 exhibits good EBR performance because the edge region of the substrate showed a removal state of a good straight shape with respect to all of EUV PR 1, EUV PR 5, and EUV PR 6. And as can be seen in Table 6, Examples 1 to 8 as a group performed better for edge bead removal than the group of comparative Examples 1 to 11.

### Experimental Example 7: Evaluation of RRC Performance with Respect to EUV Photoresist

A test was performed in such a manner that an RRC process was performed on a 12-inch oxidized silicon substrate by using each of the thinner compositions of Examples 1 to 8 and Comparative Examples 1 to 11, followed by checking whether an EUV photoresist is coated on the entire surface of the substrate. Results of the test are shown in Table 7.

TABLE 7

| Comparison | | | | | | | | | | | | | | | | | | | |
|---|---|---|---|---|---|---|---|---|---|---|---|---|---|---|---|---|---|---|---|
| of area in | Example | | | | | | | | Comparative Example | | | | | | | | | | |
| RRC coating | 1 | 2 | 3 | 4 | 5 | 6 | 7 | 8 | 1 | 2 | 3 | 4 | 5 | 6 | 7 | 8 | 9 | 10 | 11 |
| EUV PR 1 | ◯ | ◯ | ◯ | ◯ | ◯ | ◯ | ◯ | ◯ | X | X | X | X | Δ | X | X | X | X | X | X |
| EUV PR 5 | ◯ | ◯ | ◯ | ◯ | ◯ | ◯ | ◯ | ◯ | Δ | Δ | X | Δ | X | X | X | X | X | X | X |
| EUV PR 6 | ◯ | ◯ | ◯ | ◯ | ◯ | ◯ | ◯ | ◯ | X | Δ | X | X | Δ | X | X | X | X | X | X |

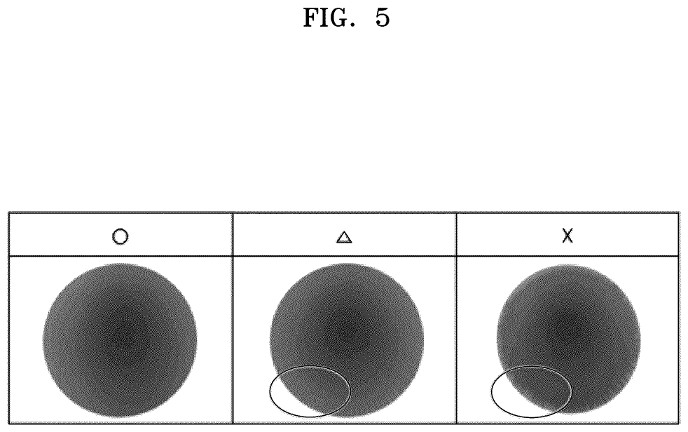

Referring to Table 7 and FIG. 5, when observation was performed by the naked eye, “O” means that the degree of coating of the photoresist was extremely good because 99% or more of the substrate area was coated with the photoresist, “Δ” means that 80% or more of the substrate area was coated with the photoresist, and “X” means that the coating of the photoresist was incomplete and an outer portion of the substrate was not coated with the photoresist and suffered from tearing.

Referring to Table 7, it can be confirmed that the thinner composition of Example 6 has high compatibility with all of EUV PR 1, EUV PR 5, and EUV PR 6 and thus may improve the RRC performance. And as can be seen from Table 7, the group of Examples 1 to 8 had a better degree of coating than the group of Comparative Examples 1 to 11.

### Experimental Example 8: Evaluation of Coating Uniformity of EUV Photoresist

An RRC process was performed on a 12-inch oxidized silicon substrate by using each of the thinner compositions of Examples 1 to 8 and Comparative Examples 1 to 11, followed by measuring the coating uniformity of an EUV photoresist. In each test, each of EUV PR 1, EUV PR 5, and EUV PR 6 was coated in the same amount, and the coating uniformity was evaluated by measuring the thicknesses of each photoresist film in a linear 29-point mode by using film thickness measurement equipment. Results regarding the maximum and minimum values of the thicknesses of the coated photoresist film measured in each test are shown in Table 8.

TABLE 8

| Uniformity | | | | | | | | | | | | | | | | | | | |
|---|---|---|---|---|---|---|---|---|---|---|---|---|---|---|---|---|---|---|---|
| in RRC | Example | | | | | | | | Comparative Example | | | | | | | | | | |
| coating | 1 | 2 | 3 | 4 | 5 | 6 | 7 | 8 | 1 | 2 | 3 | 4 | 5 | 6 | 7 | 8 | 9 | 10 | 11 |
| EUV PR 1 | ◯ | ◯ | ◯ | ◯ | ◯ | ◯ | ◯ | ◯ | X | Δ | X | X | Δ | X | X | X | X | X | X |
| EUV PR 5 | ◯ | ◯ | ◯ | ◯ | ◯ | ◯ | ◯ | ◯ | Δ | Δ | X | X | Δ | X | X | X | X | X | X |
| EUV PR 6 | ◯ | ◯ | ◯ | ◯ | ◯ | ◯ | ◯ | ◯ | Δ | Δ | X | Δ | X | X | X | X | X | X | X |

In Table 8, “O” means that the coating uniformity of the photoresist on the substrate was excellent because the difference between the maximum and minimum values was within 1% of the film thickness, “Δ” means that the coating uniformity of the photoresist on the substrate was good because the difference between the maximum and minimum values was greater than 1% and less than or equal to 5% of the film thickness, and “X” means that the coating uniformity was not good due to the poor coating of the photoresist on an edge region of the substrate because the difference between the maximum and minimum values was greater than 5% of the film thickness.

Referring to Table 8, it can be confirmed that the RRC performance improved when the thinner composition of Example 6 was used. Furthermore, as can be seen from Table 8, all of Examples 1 to 8 had excellent uniformity (max 1% variation in film thickness) whereas none of Comparative Examples 1 to 11 had this degree of uniformity.

In Experimental Examples 1 to 8, the thinner compositions used in the RRC process, which corresponds to a method of improving the coating uniformity of an EUV photoresist on a substrate and reducing the amount of an EUV photoresist used, have been described. However, the inventive concept is not limited thereto, and the thinner composition according to the inventive concept may also be applied to an RRC process of an ArF photoresist.

### Experimental Example 9: Evaluation of EBR Performance with Respect to ArF Photoresist

An EBR test was performed in such a manner that an ArF photoresist was coated on a 12-inch oxidized silicon substrate, followed by removing an unnecessary portion of the photoresist in an edge region of the substrate by using each of the thinner compositions of Example 6 and Comparative Example 7.

When EBR profiles obtained using the thinner compositions of Example 6 and Comparative Example 7 were compared, although it appeared that there was no non-uniformly coated region because no photoresist tailing was observed in the edge region of the substrate by the naked eye, it was confirmed that, when the height of a photoresist hump in the edge region of the substrate was measured, the hump height according to the thinner composition of Example 6 was 321 Å and the hump height according to the thinner composition of Comparative Example 7 was 396 Å. From these results, it can be confirmed that the thinner composition of Example 6 has better dissolving capability and compatibility with respective to an ArF photoresist as well as an EUV photoresist than the thinner composition of Comparative Example 7.

### Experimental Example 10: Evaluation of Reduction in Usage Amount of ArF Photoresist

An RRC process was performed on a 12-inch oxidized silicon substrate by using each of the thinner compositions of Example 6 and Comparative Example 7, and then, it was checked whether an ArF photoresist is coated on the entire surface of the substrate when the coating of the ArF photoresist was performed in different amounts of 0.6 cc, 0.7 cc, 0.8 cc, 0.9 cc, and 1.0 cc. Results of the test are shown in Table 9.

TABLE 9

| | 0.6 cc | 0.7 cc | 0.8 cc | 0.9 cc | 1.0 cc |
|---|---|---|---|---|---|
| Comparative | X | X | X | Δ | ◯ |
| Example 7 | | | | | |
| Example 6 | X | X | Δ | ◯ | — |

In Table 9, when observation was performed by the naked eye, “O” means that the degree of coating of the photoresist was extremely excellent because 99% or more of the substrate area was coated with the photoresist, “Δ” means that 80% or more of the substrate area was coated with the photoresist, and “X” means that the coating of the photoresist was incomplete because an outer portion of the substrate was not coated with the photoresist and suffered from tearing.

Referring to Table 9, it was confirmed that, in the case of using the thinner composition of Comparative Example 7, while the degree of coating of the photoresist was good only upon up to the use of 1.0 cc of the photoresist, in the case of using the thinner composition of Example 6, the degree of coating of the photoresist was good even when the RRC process was performed using 0.9 cc of the photoresist. From the above evaluation results, it can be numerically confirmed that the thinner composition of Example 6 may improve the RRC performance due to the high compatibility between the thinner composition of Example 6 and the ArF photoresist.

### Experimental Example 11: Evaluation of Coating Uniformity of ArF Photoresist

An RRC process was performed on a 12-inch oxidized silicon substrate by using each of the thinner compositions of Example 6 and Comparative Example 7, and then, coating uniformity was measured on an ArF photoresist. The coating uniformity was evaluated by measuring the thicknesses of the coated photoresist film in a linear 19-point mode by using film thickness measurement equipment. The maximum and minimum values of the thicknesses of the coated photoresist film and a difference between the maximum and minimum values are shown as numerical values in Table 10. All the values written in Table 10 are in units of Å.

TABLE 10

| | | Minimum | Maximum | |
|---|---|---|---|---|
| | Average | value | value | Difference |
| Comparative | 1660.5 | 1650.7 | 1672.5 | 21.9 |
| Example 7 | | | | |
| Example 6 | 1661.6 | 1653.5 | 1670.5 | 17.0 |

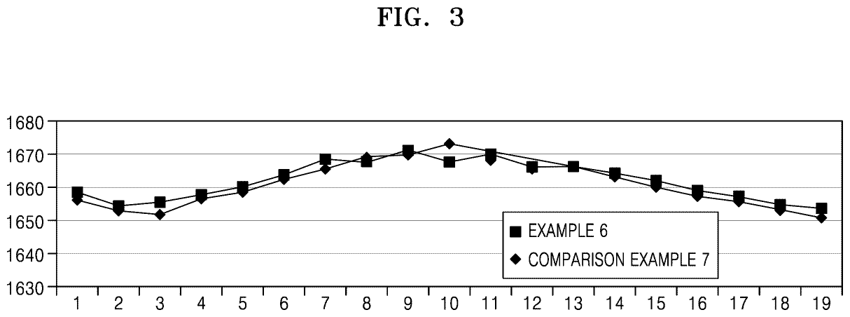

Referring to Table 10 and FIG. 3, it can be seen that the RRC process performed using the thinner composition of Example 6 showed a smaller difference between the maximum and minimum film thicknesses than the RRC process performed using the thinner composition of Comparative Example 7. That is, it can be confirmed that, in the case of using the thinner composition of Example 6, even when the coating is performed with a small amount of an ArF photoresist, the photoresist is uniformly coated on the entire area of a substrate to allow a thickness dispersion to be small. From the evaluation results, it can be numerically confirmed that the performance of the RRC process using the thinner composition of Example 6 improved.

Heretofore, the thinner composition, which exhibits improved performance in RRC and EBR and may be generally and widely used for EUV photoresists as well as KrF and ArF photoresists, has been described. Hereinafter, a thinner composition having a component weight ratio to provide an excellent pipe cleaning capability is described.

A thinner composition for pipe cleaning according to the inventive concept may include a C2-C3 alkylene glycol C1-C4 alkyl ether. The C2-C3 alkylene glycol C1-C4 alkyl ether may be present in an amount of about 20 wt % to about 40 wt % based on the total weight of the thinner composition for pipe cleaning. The C2-C3 alkylene glycol C1-C4 alkyl ether may include propyl cellosolve. The C2-C3 alkylene glycol C1-C4 alkyl ether may include at least one selected from the group consisting of ethylene glycol isopropyl ether, ethylene glycol monobutyl ether, ethylene glycol monoethyl ether, and PGME.

The thinner composition for pipe cleaning according to the inventive concept may further include a cycloketone. The cycloketone may include cyclopentanone. The cycloketone may include cyclohexanone or cycloheptanone. The cycloketone may be present in an amount of about 25 wt % to about 45 wt %.

The thinner composition for pipe cleaning according to the inventive concept may further include a C2-C4 alkylene glycol C1-C4 alkyl ether acetate. The C2-C4 alkylene glycol C1-C4 alkyl ether acetate may include PGMEA. The C2-C4 alkylene glycol C1-C4 alkyl ether acetate may be included in the thinner composition for pipe cleaning, as a material constituting the balance except for the respective proportions of the C2-C3 alkylene glycol C1-C4 alkyl ether and the cycloketone, based on the total weight of the thinner composition for pipe cleaning.

### Experimental Example 12: Evaluation of Pipe Cleaning Capability of Thinner Composition

A KrF photoresist, an ArF photoresist, and an EUV photoresist, which were concentrated, were each coated on a substrate and baked on a hot plate, followed by immersing each photoresist in each of the thinner compositions of Example 7 and Comparative Examples 8 and 9, and then, time periods until it is observed by the naked eye that all solid residues disappear were compared. The substrates coated with the KrF photoresist were baked at 200° C. for 5 minutes and 7 minutes, respectively, followed by measuring a time period until the KrF photoresist is dissolved. The substrates coated with the ArF photoresist were baked at 130° C. for 1 minute and 3 minutes, respectively, followed by measuring a time period until the ArF photoresist is dissolved. The substrates coated with the EUV photoresist were baked at 200° C. for 5 minutes and 7 minutes, respectively, followed by measuring a time period until the EUV photoresist is dissolved.

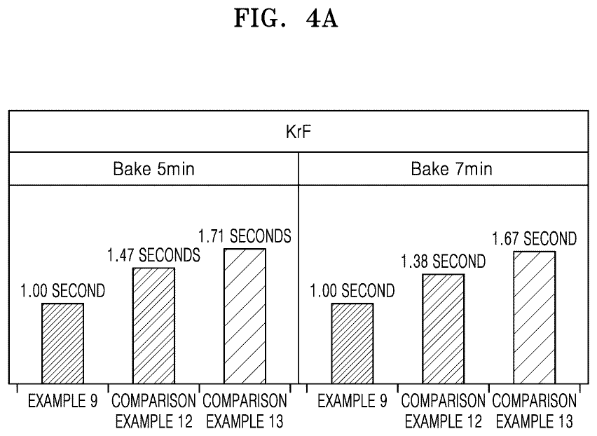

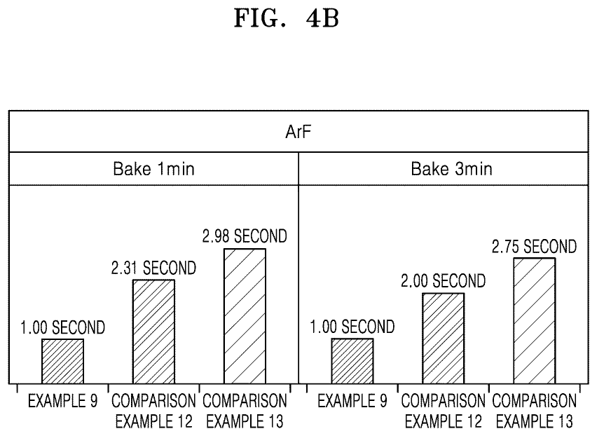

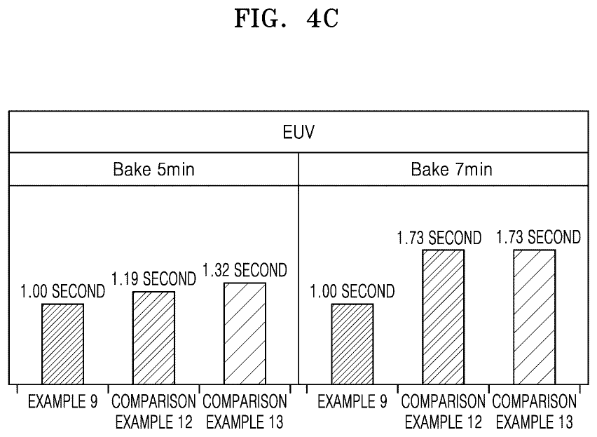

Results of evaluating the dissolving capabilities of each thinner composition for pipe cleaning with respect to the KrF photoresist, the ArF photoresist, and the EUV photoresist are shown in FIGS. 4A to 4C, respectively. In addition, respective component ratios of the thinner compositions of Example 7 and Comparative Examples 9 and 10 are shown in Table 11. The numerical values written in Table 11 are in units of wt %.

TABLE 11

| | PGMEA | PC | CPN | PGME |
|---|---|---|---|---|
| Example 7 | 35 | 30 | 35 | |
| Comparative | | | | 100 |
| Example 9 | | | | |
| Comparative | 30 | | | 70 |
| Example 10 | | | | |

Referring to the result of FIG. 4A, it can be confirmed that the thinner composition of Example 7 has an improved dissolving capability with respect to the KrF photoresist by as much as 40% compared with the thinner composition of Comparative Example 9. Referring to the result of FIG. 4B, it can be confirmed that the thinner composition of Example 7 has an improved dissolving capability with respect to the ArF photoresist by as much as 100% compared with the thinner composition of Comparative Example 9. Referring to the result of FIG. 4C, it can be confirmed that the thinner composition of Example 7 has an improved dissolving capability with respect to the EUV photoresist by as much as 70% compared with the thinner composition of Comparative Example 9.

According to the inventive concept, a method of treating a substrate surface includes coating, on a substrate, a thinner composition, which includes a C2-C4 alkylene glycol C1-C4 alkyl ether acetate, a C2-C3 alkylene glycol C1-C4 alkyl ether, and a cycloketone, forming a photoresist film by applying a photoresist composition to the substrate and heating the substrate, exposing at least a portion of the photoresist film to light, and developing the photoresist film that is exposed to light.

The substrate may include, for example, a semiconductor substrate, such as a silicon substrate or a germanium substrate, glass, quartz, ceramic, copper, or the like. In some embodiments, the substrate may include a Group III-V compound, such as GaP, GaAs, or GaSb.

A coating method of the substrate may include spin coating, dipping, roller coating, or other general coating methods. Among the coating methods set forth above, spin coating may be used in particular, and the photoresist film having an intended thickness may be formed by adjusting the viscosity and concentration of the photoresist composition and/or the spin speed. The photoresist composition, which is used in the method of treating a substrate surface, may include a KrF photoresist, an ArF photoresist, or an EUV photoresist.

Before the photoresist composition is applied on the substrate, an etching target film may be further formed on the substrate. The etching target film may refer to a layer, which is to be converted into a certain pattern through the transfer of an image from a photoresist pattern thereto. In an embodiment, the etching target film may include, for example, an insulating material, such as silicon oxide, silicon nitride, or silicon oxynitride. In some embodiments, the etching target film may include a conductive material, such as a metal, a metal nitride, a metal silicide, or a metal silicide nitride film. In some embodiments, the etching target film may include a semiconductor material, such as polysilicon.

In an embodiment, an anti-reflective coating film and a photoresist film may be sequentially formed in the stated order on the etching target film. Next, at least a portion of the photoresist film may be exposed to a high-energy ray. For example, the high-energy ray passing through a mask may be irradiated onto at least a portion of the photoresist film. Thus, the photoresist film may have an exposed portion and a nonexposed portion. The high-energy ray may have a wavelength of 250 nm or less. Specifically, the high-energy ray may include an ArF excimer laser light having a wavelength of 193 nm or an EUV light. If EUV light, the light source may provide light at e.g., a wavelength of about 13.5 nm or less, and may be from a laser-produced plasma based on irradiating tin (Sn) microdroplets by a high-energy nanosecond pulsed laser, and where the mask may be a multilayer mask with many pairs of alternating high and low index of refraction materials, such as from 35 to 55 pairs of high index of refraction layer (to scatter EUV light)+low index of refraction layer (to transmit EUV light), such as 40 to 50 pairs of molybdenum-silicon layers in the mask.

Next, the photoresist film that is exposed may be developed by using a developer. A development method may include spin development, dipping, puddle development, or the like, and development time may include a period of time that is effective to remove the exposed portion of the photoresist film.

Here, the C2-C4 alkylene glycol C1-C4 alkyl ether acetate may include PGMEA. Here, the C2-C3 alkylene glycol C1-C4 alkyl ether may include at least one selected from the group consisting of propyl cellosolve, ethylene glycol isopropyl ether, ethylene glycol monobutyl ether, ethylene glycol monoethyl ether, and propylene glycol monomethyl ether. Here, the cycloketone may include at least one selected from the group consisting of cyclopentanone, cyclohexanone, and cycloheptanone.

The thinner composition, which is provided to the method of treating a substrate surface, may include about 20 wt % to about 40 wt % of the C2-C3 alkylene glycol C1-C4 alkyl ether and about 5 wt % to about 20 wt % of the cycloketone, based on the total weight of the thinner composition.

As in the method set forth above, when the thinner composition is sprayed on a substrate before photoresist coating, the wetting of the substrate may improve before photoresist coating, thereby forming a photoresist film to a uniform thickness even with a small amount of the photoresist. In addition, in a subsequent process of removing an unnecessary portion of the photoresist film in an edge region of the substrate (that is, in an EBR process), the removal of the photoresist film may be effectively performed without generating a tailing phenomenon.

While the inventive concept has been particularly shown and described with reference to embodiments thereof, it will be understood that various changes in form and details may be made therein without departing from the spirit and scope of the following claims.

What is claimed is:

1. A thinner composition comprising:
a C2-C4 alkylene glycol C1-C4 alkyl ether acetate;
a C2-C3 alkylene glycol C1-C4 alkyl ether; and
a cycloketone.

2. The thinner composition of claim 1, wherein the C2-C4 alkylene glycol C1-C4 alkyl ether acetate comprises propylene glycol monomethyl ether acetate (PGMEA).

3. The thinner composition of claim 1, wherein the C2-C3 alkylene glycol C1-C4 alkyl ether comprises at least one selected from the group consisting of ethylene glycol isopropyl ether, ethylene glycol monopropyl ether, ethylene glycol monobutyl ether, ethylene glycol monoethyl ether, and propylene glycol monomethyl ether (PGME).

4. The thinner composition of claim 1, wherein the C2-C3 alkylene glycol C1-C4 alkyl ether comprises ethylene glycol monopropyl ether.

5. The thinner composition of claim 1, wherein the cycloketone comprises cyclopentanone (CPN).

6. The thinner composition of claim 1, wherein the cycloketone comprises at least one of cyclohexanone and cycloheptanone.

7. The thinner composition of claim 1, further comprising a silicone-based surfactant.

8. The thinner composition of claim 1, wherein the C2-C4 alkylene glycol C1-C4 alkyl ether acetate is present in an amount of about 50 wt % to about 80 wt % based on the total weight of the thinner composition.

9. The thinner composition of claim 1, wherein the C2-C3 alkylene glycol C1-C4 alkyl ether is present in an amount of about 20 wt % to about 40 wt % based on the total weight of the thinner composition.

10. The thinner composition of claim 1, wherein the cycloketone is present in an amount of about 5 wt % to about 20 wt % based on the total weight of the thinner composition.

11. The thinner composition of claim 1, wherein the thinner composition is used in a reduced resist coating (RRC) process, an edge bead removal (EBR) process, a rework process, and a wafer backside cleaning process, which are based on KrF, ArF, and extreme ultraviolet (EUV) photoresists.

12. The thinner composition of claim 1, wherein the C2-C4 alkylene glycol C1-C4 alkyl ether acetate is present in an amount of about 20 wt % to about 40 wt % based on the total weight of the thinner composition.

13. The thinner composition of claim 1, wherein the cycloketone is present in an amount of about 25 wt % to about 45 wt % based on the total weight of the thinner composition.

14. The thinner composition of claim 1, wherein the thinner composition is used for pipe cleaning.

15. A thinner composition comprising:
propylene glycol monomethyl ether acetate (PGMEA);
ethylene glycol monopropyl ether (EGPE); and
cyclopentanone (CPN).

16. The thinner composition of claim 15, wherein PGMEA is present in an amount of about 30 wt % to about 80 wt % based on the total weight of the thinner composition,
EGPE is present in an amount of about 10 wt % to about 50 wt % based on the total weight of the thinner composition, and
CPN is present in an amount of about 2 wt % to about 40 wt % based on the total weight of the thinner composition.

17. A method of treating a substrate surface, the method comprising:
coating a thinner composition on a substrate;
forming a photoresist film by applying a photoresist composition to the substrate and heating the substrate;
exposing at least a portion of the photoresist film to light; and
developing the photoresist film that is exposed to light,
wherein the thinner composition comprises:
a C2-C4 alkylene glycol C1-C4 alkyl ether acetate;
a C2-C3 alkylene glycol C1-C4 alkyl ether; and
a cycloketone.

18. The method of claim 17, wherein the C2-C4 alkylene glycol C1-C4 alkyl ether acetate comprises propylene glycol monomethyl ether acetate,
the C2-C3 alkylene glycol C1-C4 alkyl ether comprises propyl cellosolve, and
the cycloketone comprises cyclopentanone.

19. The method of claim 17, wherein the C2-C4 alkylene glycol C1-C4 alkyl ether acetate is present in an amount of about 10 wt % to about 50 wt % based on the total weight of the thinner composition, and
the cycloketone is present in an amount of about 2 wt % to about 40 wt % based on the total weight of the thinner composition.

20. The method of claim 17, wherein the photoresist composition comprises at least one selected from the group consisting of an extreme ultraviolet (EUV) photoresist, a KrF photoresist, and an ArF photoresist.
